(19) United States
(12) Patent Application Publication
(10) Pub. No.: US 2007/0166971 A1
(43) Pub. Date: Jul. 19, 2007

(54) MANUFACTURING OF SILICON STRUCTURES SMALLER THAN OPTICAL RESOLUTION LIMITS

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/425,364

(22) Filed: Jun. 20, 2006

Related U.S. Application Data
(63) Continuation-in-part of application No. 11/333,117, filed on Jan. 17, 2006.

(51) Int. Cl. H01L 21/3205; H01L 21/44

(52) U.S. Cl. 438/585; 438/595; 438/669; 438/671; 438/947

(57) ABSTRACT

Method for forming silicon structures, such as upright gates or fins on a wafer substrate, particularly for use as a building block for semiconductor devices. The structures are smaller than can be resolved by conventional optical lithography. A plan of the area-wise dimensions of the fin or gate structure is mapped to a substrate as an ideal, Conductive and insulative layers are deposited onto the substrate and a work region that includes the desired structure is designed by photolithography. An opening is etched in the work region and a frame is created protective of the desired structure. Most of the frame is etched away except over the structure and then this portion is used to protect the structure so that remaining material can be removed until only the gate over the substrate remains. This process is carried out in many places over a wafer with the structures preferably aligned in rows and columns for making memory or logic arrays.

### CROSS-REFERENCE TO RELATED APPLICATION

This application is a continuation-in-part of prior application Ser. No. 11/333,117, filed Jan. 17, 2006.

### TECHNICAL FIELD

The invention relates to integrated circuit manufacturing and, in particular to manufacturing structures, such as fins or gates on wafer substrates.

### BACKGROUND OF THE INVENTION

There are known techniques for construction of devices with features smaller than the limits of optical resolution. A first technique is to use the edges of lines that are optically resolved to define small gaps less than the limits of optical resolution to allow building of features, for example, by diffusion and growth in a gap, or by implantation. A second technique is to build large features, then etch the features to a sliver or spacer. The sliver can act as a mask allowing construction of devices on sides of the sliver or the sliver may be a building material or define a hole. For example, see U.S. Pat. No. 5,026,663 to P. Zdebel et al. or U.S. Pat. No. 6,194,829 to N, Lu. An upright freestanding sliver is sometimes called a fin or spacer. Various types of semiconductor structures can use silicon fins, such as MOS transistors known as surrounding gate transistors or finfets. A potential application is in forming a transistor or a transistor memory device.

As transistor dimensions become smaller, it becomes more difficult to scale devices downwardly and to provide appropriate voltages to floating gate transistors for selection, read, write and erase. The typical array is a planar structure fabricated on a silicon chip with vertical “tunnels” called vias making contact with lower chip levels where appropriate voltages are needed. Since present day dimensions for transistors are at the limits of photolithography, it becomes difficult to pattern vias. The precision registration required between overlying masks or layers of a chip is a difficult task in manufacturing EEPROMs of the smallest size since the characteristic sizes of desired features is smaller than characteristic sizes of the vias. In other words, desired features, such as gates, would have to be made larger to accommodate vias and so devices are not scalable to smaller dimensions.

One of the complicating factors in chip manufacturing is the need to repeat photolithographic patterns over the surface of a wafer for each chip to be manufactured. A special tool known as a step-and-repeat camera, sometimes called a “stepper”, is used to pattern a wafer with the many layers of mask patterns, repeated for each device to be made on a wafer. As devices become smaller, alignment problems arise from layer to layer, with stepper tools having a very high level of sophistication and expense to achieve desired tolerances.

An objects of the invention is to devise an array of fins on a semiconductor substrate.

A further object of the invention is to make gate structures that are smaller than the limits of optical resolution that can serve as building blocks for device manufacturing, or for testing manufacturing tools.

### SUMMARY OF INVENTION

The present invention is a new method of integrated circuit construction for upright structures, particularly silicon arrays of such structures on a common wafer, built as microminiature bars or fins, aligned in rows with each structure being smaller than the limits of optical resolution. Steppers image an optical pattern onto a wafer. The present invention allows construction of features smaller than the smallest line that can be made with steppers. Treating the structures as gates, after ion implantation for source and drain, and after formation of contacts, the silicon gates of the present invention can be finished as transistors, sometimes called “finfets”. The spacing between the rows of gates, as well as the height of the gates and thickness of the gates is scaleable, almost down to the vanishing point. For example, rows and columns of gates, with the gates used to make memory transistors, could be a memory array so long as needed electrical contacts and inter-connections can be made with the top, bottom, or sides of the gates. Since many millions of gates could be fabricated on a wafer, the dimensions of a complicated device, such as a processor becomes much smaller, power requirements are smaller and speed limitations arising from interconnect distances are reduced since everything is more compact. The structures could be made from any of amorphous-silicon, polysilicon, and silicon.

The first step is to design the desired structure area dimensions taking into account the number of devices that are needed, their spacing, and their interconnection. Once the desired structure area dimensions are established in a plan, the structure dimensions are mapped by imagination or design onto a location on a wafer substrate. No marks are made on the wafer or substrate but a location is established for the gate that is known within fabrication equipment. The structure cannot be drawn or marked on a wafer because at least the structure length is smaller than optical resolution limits. Thus, the mapping is a theoretical mapping of a desired length and width for a structure on an oxide covered substrate or on other materials used in semiconductor manufacturing. Next, the substrate is covered with a first layer of structure material, such as a first layer of polysilicon or other suitable material. Polysilicon when appropriately doped is a conductive material and is ubiquitous as a gate material. Next, a layer of TEOS over a thin oxide layer supports photoresist that used to define a rectangular work region enclosing the mapped structure region. A central opening is then etched in the work region through the TEOS layer and a layer of nitride or a second layer of polysilicon (“poly two”) is deposited around and into the central opening. By further etching the central opening a frame of poly two or nitride will exist as a boundary of the work region. The mapped structure region is located or thickness dimension corresponding to the desired length of a gate region where the structure is a gate. Photoresist is now used to protect a portion of the frame corresponding to at least the length and width of the gate region. Next, the unprotected portion of the frame is removed, leaving a protected frame portion over the mapped gate region. Next, the protected frame portion is used as a mask over the mapped structure region to remove remaining first layer material and remaining frame portions, thereby leaving the mapped structure region of first layer material over the substrate.

This procedure is carried out millions of places on a wafer surface with the structures appearing as tiny silicon fins or gates. As is known, such fins are building blocks for transistors or other devices. When aligned in rows and columns, the fins can be used to make semiconductor memories. Sources and drains must be formed, typically by implantation, and word and bit lines must be established, either by subsurface connections or top contacts and traces. A wafer with silicon fins is an article of manufacture, similar to a base wafer, with many uses beyond building devices of various types, such as memory devices, logic devices, and processors.

### BRIEF DESCRIPTION OF DRAWINGS

FIGS. 1, 3, 5, 7, 9, 11, 13, 15, 17, 19, 21, and 23 are top plan views of manufacturing steps for devices of the present invention.

FIGS. 2, 4, 6, 8, 10, 12, 14, 16, 18, 20, and 22 are side views of manufacturing steps for devices of the present invention.

### DESCRIPTION OF INVENTION

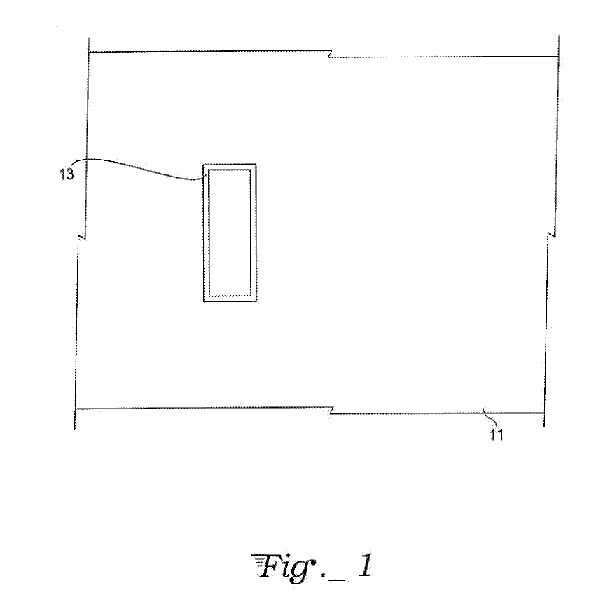

With reference to FIG. 1, a silicon substrate 11 is shown having an imaginary boundary 13 within which a bar or silicon fin structure of the present invention will be located. The boundary 13 exists on a plan or a computer memory and by a manufacturing plan is to be shrunk to a desired location of a substrate such that the area shown within the boundary is smaller than the limits of optical resolution and therefore could not be imaged with a microscope or lenses. The bar or fin structure is thus mapped onto a planned location on the substrate. Substrate 11 is a semiconductor wafer that could have millions of silicon fin structures constructed on its surface aligned in rows, as building blocks for semiconductor devices such as transistor gates. For example, the width dimension within boundary 13 is less than 100 nanometers and the length dimension would be several hundred nanometers, or less, say less than 400 nanometers, or less than 40,000 square nanometers. Such a small area-wise cross-sectional or top view dimension cannot be imaged, except that rows of similar devices can form diffraction patterns for light. The utility of silicon gates formed within the boundary 13 is that such gates can be used to form transistors upon implantation of sources and drains on either side and upon making contact with electrodes of the device, either by vias or conductive paths to electrodes. Such paths are disclosed in my co-pending application Ser. No. 11/333,117, filed Jan. 17, 2006.

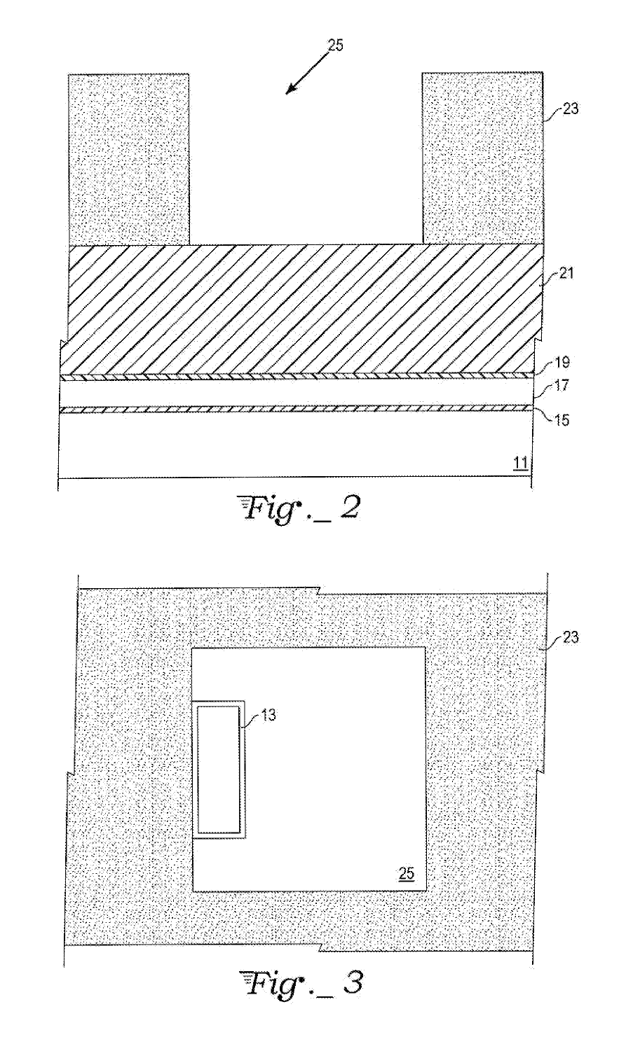

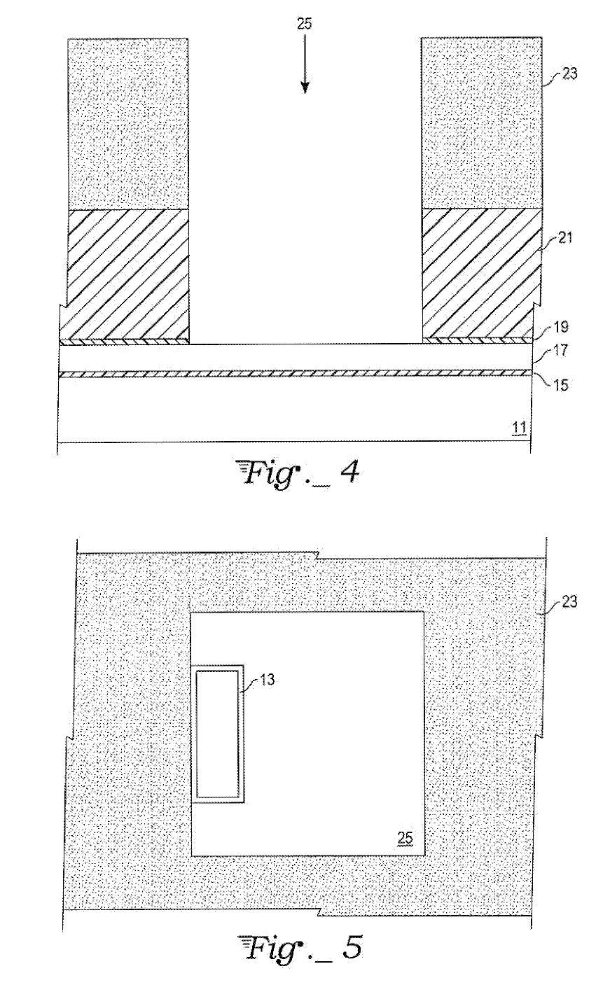

With reference to FIG. 2, the substrate 11 is seen to be coated with a thin layer of gate oxide 15 approximately 20 angstroms thick. Substrate 11 is typically a doped semiconductor p-type or n-type wafer suitable for manufacture of MOS devices. A first layer of polysilicon 17 is deposited over the gate oxide layer 15 by vapor deposition to a thickness of approximately 1500 angstroms, or whatever dimension is desired for the height of a silicon gate which will be the finished structure. Over the polysilicon layer 17 another layer of oxide 19 is deposited having a thickness of approximately 20-30 angstroms. Over the second layer of oxide 19 an insulative oxide layer 21, preferably a TEOS layer is deposited having a thickness which is approximately 2.5 times the thickness of polysilicon layer 17. It should be noted that the layers 15, 17, 19, and 21 are all planar layers extending entirely across the wafer substrate. Over the TEOS layer 21 a full resist layer 23 is deposited with an opening 25 defined by a photomask, with opening establishing a rectangular work region. The opening 25 is ideally the smallest opening that can be defined by a mask. In the top view of FIG. 3, the opening 25 is many times bigger than boundary 13. Photoresist layer 23 is seen to completely surround opening 25. The TEOS layer 21 in the center of opening 25 is etched, as shown in FIG. 4. Etching is stopped at polysilicon layer 17, meaning that oxide layer is also removed in the opening 25.

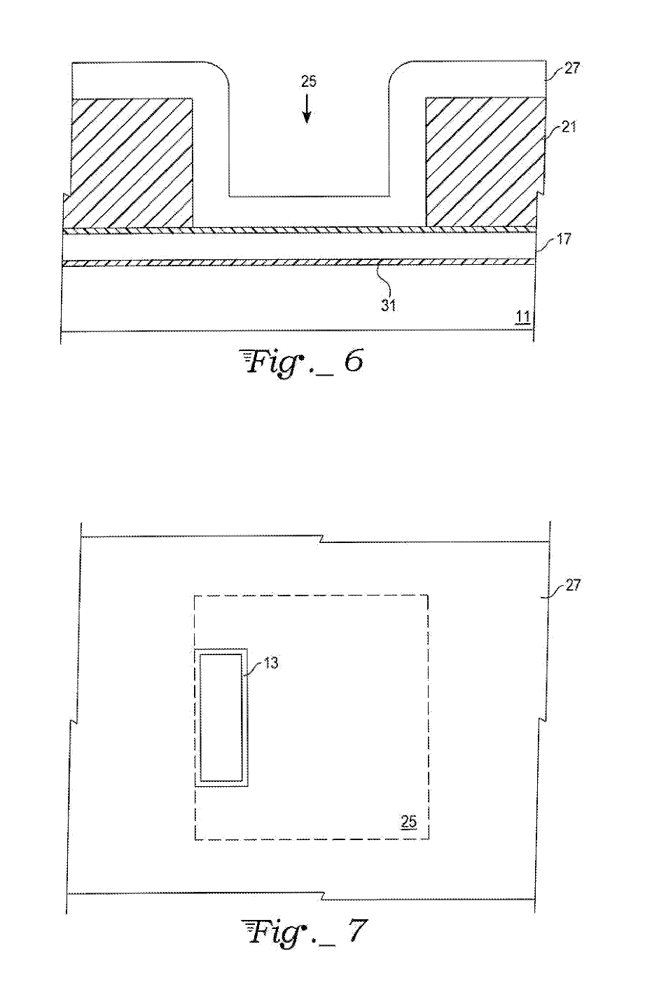

FIG. 5 shows that the photoresist layer 23 still completely surrounds opening 25, i.e., the work region, prior to its removal. After removal of the photoresist, as shown in FIG. 6, a nitride or polysilicon layer 27 is deposited over the TEOS layer 21 with the layer 27 extending down into the opening 25. Prior to deposition of the layer 27 the polysilicon layer 17 is reoxidized so that oxide will separate the nitride or poly layer 27 from polysilicon layer 17 in the region 31 where reoxidation occurs.

In the top view of FIG. 7, the entire wafer appears to be covered by polysilicon layer 27 with the dashed line indicating the boundary of opening 25 and imaginary boundary 13 shown within opening 25. The work region is now lined with polysilicon layer 27, i.e., poly two, with poly extending over the TEOS also.

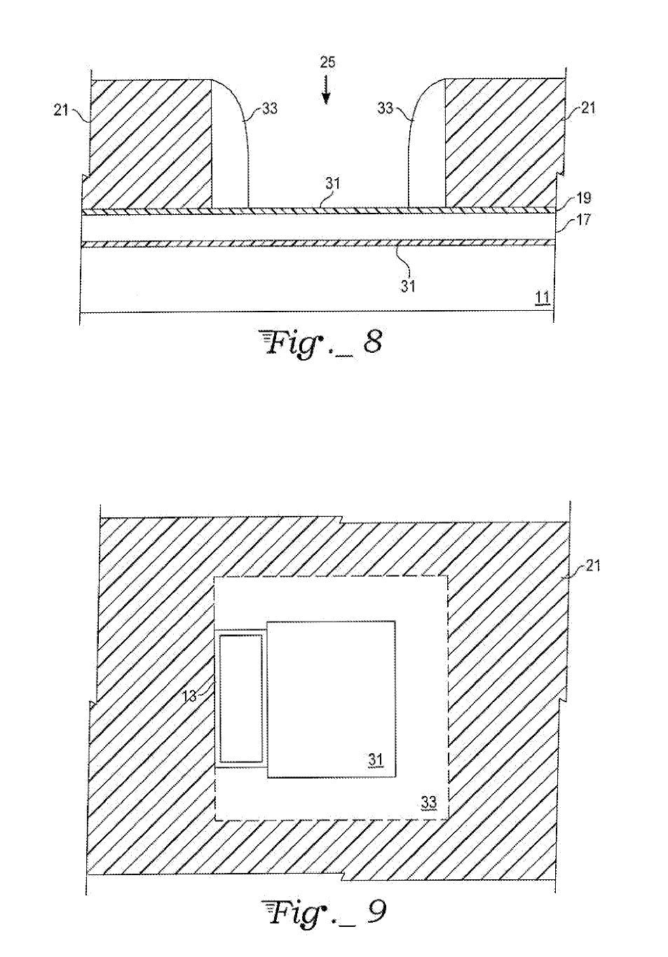

Next, the polysilicon or nitride layer 27 is mostly etched away, except for a spacer rectangle 33, seen in FIGS. 8 and 9, which abuts the TEOS layer 21 in opening 25. This is more clearly seen in FIG. 9 where the further etching of the polysilicon or nitride layer 33 forms a four-sided frame around oxide portion 31 within opening 25. The width of the spacer rectangle corresponds to the width of boundary 13 for the silicon gate to be constructed.

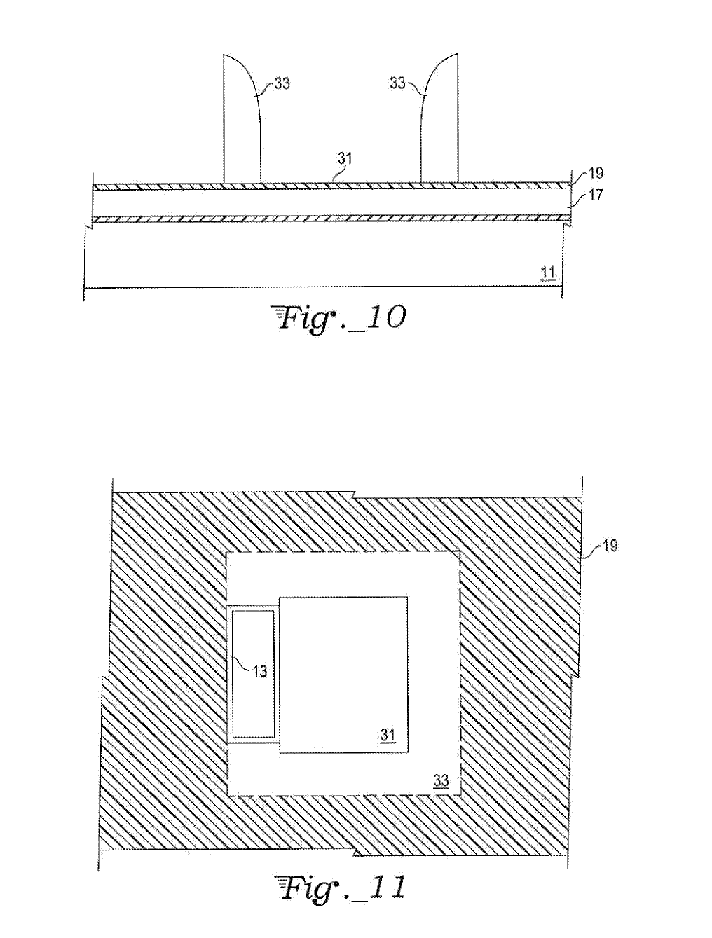

In FIG. 10, the TEOS layer is seen to be removed, leaving the polysilicon or nitride rectangle 33 that forms a frame over the oxide layer 31 and 19. This is seen again in FIG. 11.

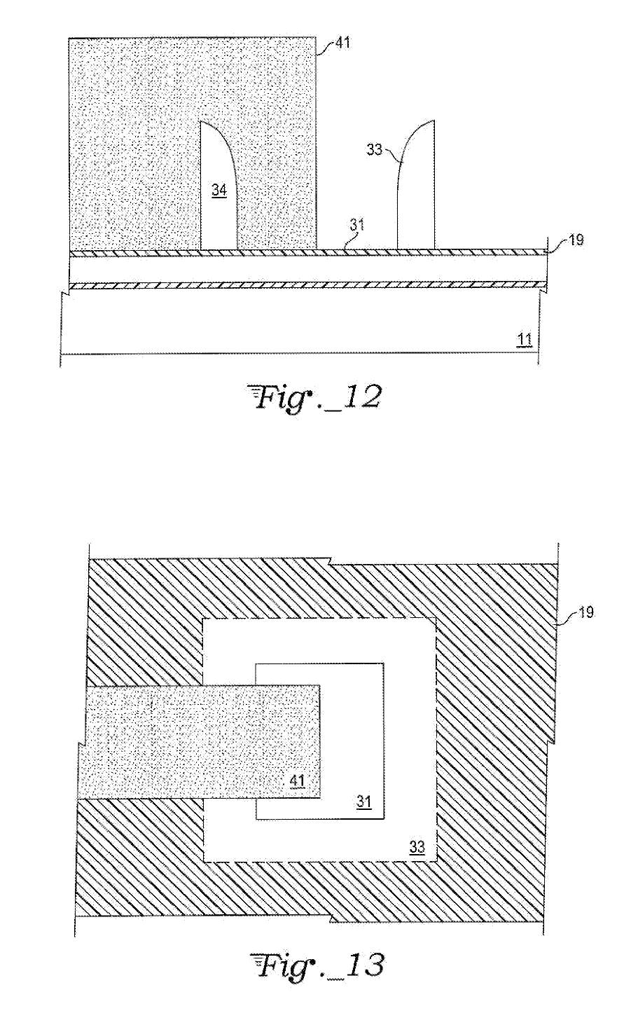

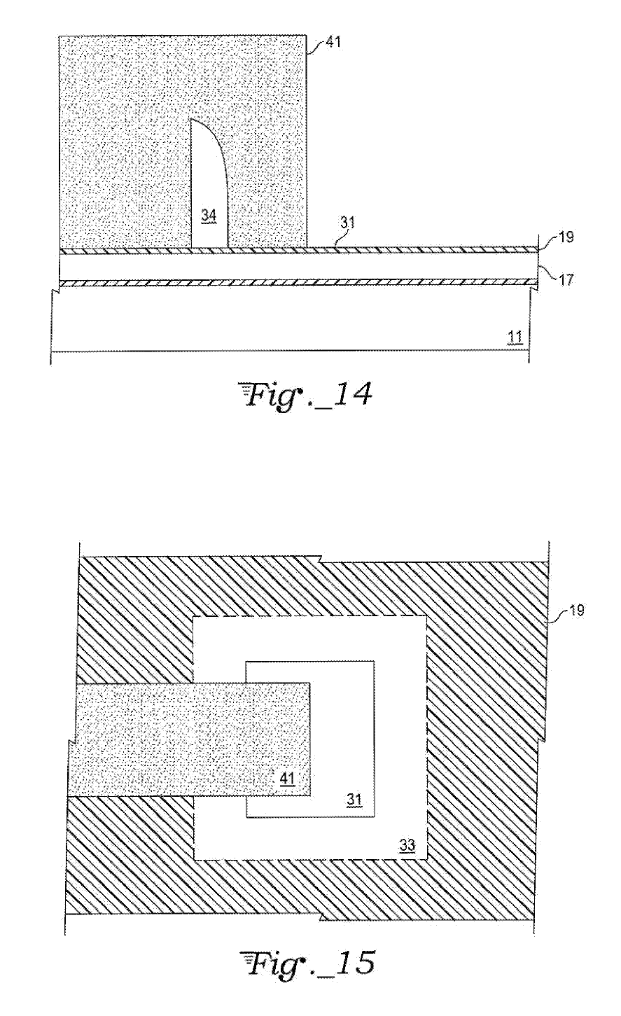

In FIG. 12 and 13, a stripe of photoresist 41 is seen to cover a portion of the spacer rectangular 33. The photoresist stripe 41 has a dimension equal to the length dimension of the boundary 13 and protects the polysilicon or nitride spacer portion beneath the photoresist. Note that the photoresist stripe 41 that corresponds to a dimension of the desired gate can be formed by edges of photomasks and cannot be imaged as a line. In FIG. 14, the non-protected portion is etched away down to oxide layers 31 and 19 atop polysilicon layer 17. The protected portion of the polysilicon or nitride rectangle is the single spacer 34. The removed portion of the polysilicon or nitride rectangle 33 is indicated by cross-hatched lines in FIG. 15.

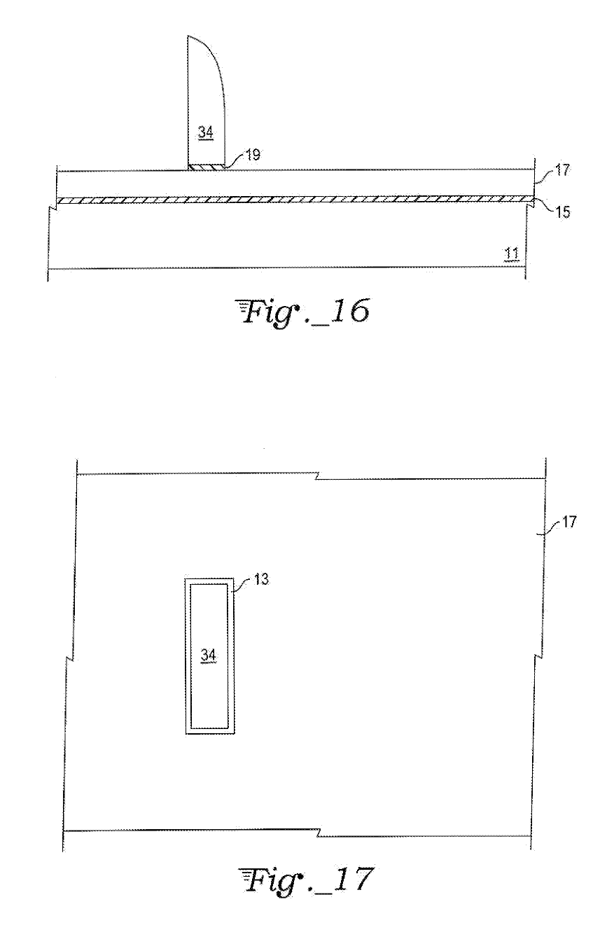

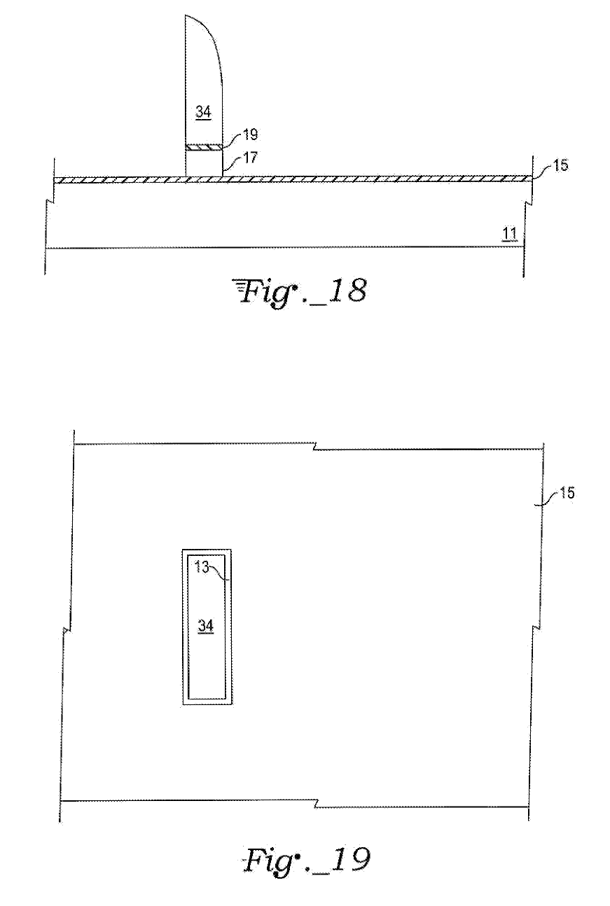

In FIGS. 16 and 17, the polysilicon or nitride spacer 34 is etched to remove the photoresist layer, as well as oxide regions 31 and 19, except for oxide region 19 underneath spacer 34. Polysilicon layer 17 remains above the gate oxide layer 15 which, in turn, is a top substrate portion 11. In FIG. 17, the area-wise footprint of spacer 34 is seen to correspond to the imaginary boundary 13 atop the polysilicon layer 17. In FIGS. 18 and 19, the polysilicon layer 17 is etched, leaving a polysilicon gate 17 on gate oxide layer 15. The etch reduces the size of the polysilicon or nitride spacer 34 which is atop a oxide layer 19.

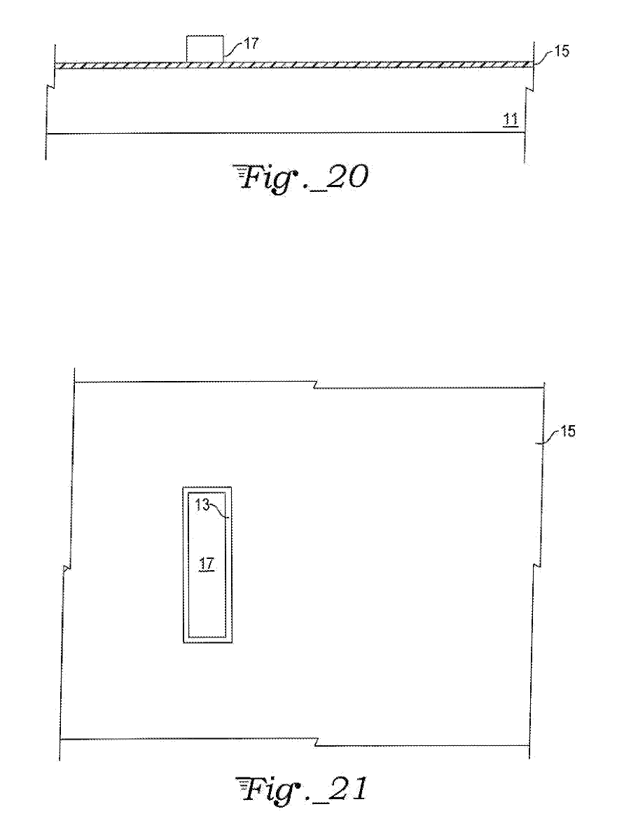

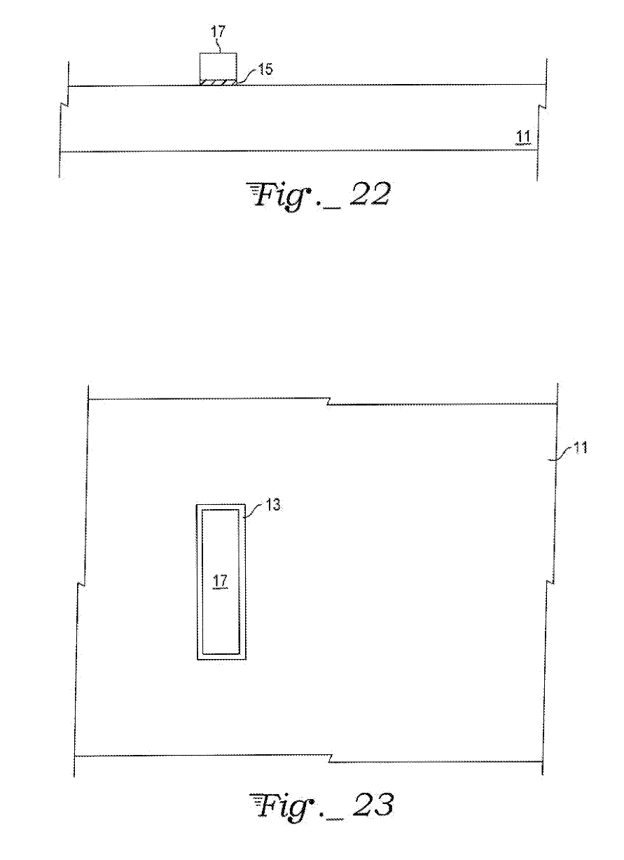

In FIGS. 20 and 21, the polysilicon gate 17 has been subject to etching, removing the spacer and oxide material 19. The polysilicon structure 17 is atop oxide layer 15 and occupies the entire space within the imaginary boundary 13, as shown in FIG. 21. Lastly, the oxide layer 15 is etched, as seen in FIGS. 22 and 23, leaving the polysilicon structure 17 atop a small oxide region 15 residing on wafer 11. It has been shown that the polysilicon structure 17 is a bar-like or fin-like region within the imaginary boundary 13 that is smaller than the limits of optical resolution. When similar members are aligned in rows, millions of similar structures can be fabricated on a silicon wafer and form building blocks for transistors, such as gates requiring doping of the substrate on opposite sides of each gate and making connections to transistor electrodes by subsurface contacts and contacts communicating with the gates, Such structures need not solely be polysilicon, but could be amorphous silicon, silicon or other semiconductor material. An entire wafer surface can have such rows of gates as an article of manufacture, with selected spacing between rows and the pitch of the gates.

What is claimed is:

1. The method of making a microminiature structure on a planar substrate comprising:
mapping a structure region of desired dimensions smaller than optical resolution from a plan onto a wafer substrate;
providing selected structure material over a wafer substrate region that includes the mapped structure;
protecting structure material over the mapped structure region with a mask that is larger in area-wise extent than the mapped structure reducing the area of the protected structure material to correspond to the structure area;
removing unprotected structure material from the substrate; and
removing the mask, thereby exposing the structure material on the wafer substrate region as a structure smaller than optical resolution limits.

2. The method of claim 1 wherein said mask is a rectangular frame.

3. The method of claim 3 wherein the rectangular frame is defined by etching an opening in said mask.

4. The method of claim 1 further defined by simultaneously manufacturing a plurality of structures smaller than optical resolution limits.

5. The method of claim 4 wherein said structures are aligned in rows.

6. The method of claim 4 wherein said structures made of material selected from the group of amorphous silicon, polysilicon, and silicon.

7. The method of claim 4 wherein said wafer is doped on sides of the structures to form transistors.

8. The method of claim 5 wherein said structures cover the surface of a wafer.

9. A method of making a microminiature structure on a planar substrate comprising:
mapping a structure region from a plan onto a substrate, the mapped structure region having a length and width, the length being smaller than optical resolution limits;
covering the substrate with a first layer of structure material;
forming an optically resolved work region with a second layer over the first layer within a photoresist boundary that encloses the structure region;
etching an opening in the work region, through the second layer;
creating a frame, of second layer material around the opening an the work region covering the mapped structure region, the frame having a length dimension corresponding to the length of the structure region;
protecting a portion of the frame corresponding to at least the length and width of the structure region;
removing the unprotected portion of the frame leaving a protected frame portion over the mapped structure region;
using the protected frame portion as a mask to protect the mapped structure region in the first layer as a structure, while removing remaining first layer material; and
removing all remaining frame portions to leave the mapped region as a structure in the first layer over the substrate.

10 . The method of claim 9 wherein said substrate is a silicon wafer with an insulative coating.

11. The method of clam 10 wherein the first layer is a conductive layer.

12. The method of claim 10 wherein the first layer is a polysilicon one layer.

13. The method of claim 9 wherein the protecting a portion of the frame corresponding to at least the length and width of the gate region is by photoresist.

14. The method of claim 9 wherein the second layer material is a polysilicon two layer.

15. The method of claim 9 wherein the second layer material is a nitride layer.

16. The method of claim 9 simultaneously replicated a plurality of times on the same substrate.

17. The method of claim 16 wherein replicated gate structures are aligned in rows.

18. The method of claim 16 wherein replicated gate structures are rows and columns.

19. The method of claim 9 wherein the frame is created by photolithographic patterning and etching.

20. The method of making polysilicon fins arrays on a wafer substrate comprising;
mapping rows of polysilicon fins having dimensions smaller than optical resolution limits onto a wafer, each fin separated from another by dimensions of an optically resolved work region;
coating the wafer with a first layer of polysilicon;
defining the work regions with a second layer over the first layer, each work region having a boundary that encloses a mapped fin;
etching openings in the work region through the second layer to create frames;
protecting a frame portion for each frame corresponding to at least one fin dimension;
removing the unprotected portion of the frames leaving protected frame portions over the mapped fins;
using the protected frame portions as a mask to protect the mapped fins in the first layer as polysilicon fins, while removing remaining first layer material; and
removing all remaining frame portions to leave polysilicon fins in the first layer over the substrate.
